(19) United States
(12) Patent Application Publication
(10) Pub. No.: US 2025/0344482 A1
(43) Pub. Date: Nov. 6, 2025

(54) SEMICONDUCTOR DEVICE, SEMICONDUCTOR DEVICE MANUFACTURING METHOD, AND ELECTRONIC DEVICE

(71) Applicant: Fujitsu Limited, Kawasaki-shi (JP)

(72) Inventors: Kenji HOMMA, Atsugi (JP); Atsushi YAMADA, Hiratsuka (JP)

(73) Assignee: Fujitsu Limited, Kawasaki-shi (JP)

(21) Appl. No.: 19/191,860

(22) Filed: Apr. 28, 2025

(30) Foreign Application Priority Data
May 1, 2024 (JP) 2024-074326

(51) Int. Cl. H10D 64/27; H10D 30/01; H10D 30/47; H10D 62/85; H10D 64/01

(52) U.S. Cl. CPC H10D 64/411; H10D 30/015; H10D 30/475; H10D 62/8503; H10D 64/01

(57) ABSTRACT

A semiconductor device includes a substrate, a first layer provided on a first surface side of the substrate, the first layer containing a first element at a first concentration and having a first opening, and a second layer provided between the first surface of the substrate and the first layer, the second layer containing the first element at a second concentration different from the first concentration and having a second opening communicating with the first opening of the first layer, the second opening having an opening width smaller than that of the first opening.

### CROSS-REFERENCE TO RELATED APPLICATION

This application is based upon and claims the benefit of priority of the prior Japanese Patent Application No. 2024-074326, filed on May 1, 2024, the entire contents of which are incorporated herein by reference.

### FIELD

The embodiments discussed herein relate to a semiconductor device, a semiconductor device manufacturing method, and an electronic device.

### BACKGROUND

For example, with respect to nitride semiconductor devices, a technique is known in which an aluminum-free nitride semiconductor layer is formed at a deposition temperature that decreases toward the front surface, and the nitride semiconductor layer is etched to form a recess having an inclined side wall where the opening on the front surface side is wider (for example, see Japanese Laid-open Patent Publication No. 2009-164437).

In addition, with respect to field-effect compound semiconductor devices, a technique is known in which a multilayer structure film including two or more layers having different compositions or densities is formed as an insulating film, and the insulating film is etched to form a gate opening portion including steps corresponding to the number of layers of the multilayer structure film (for example, see Japanese Laid-open Patent Publication No. 2015-72962).

### SUMMARY

In one aspect, there is provided a semiconductor device including: a substrate having a first surface on a first surface side thereof; a first layer provided on the first surface side of the substrate, containing a first element at a first concentration, and including a first opening with a first opening width; and a second layer provided between the first surface of the substrate and the first layer, containing the first element at a second concentration different from the first concentration, and including a second opening with a second opening width smaller than the first opening width, the second opening communicating with the first opening of the first layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are diagrams for describing a first example of a semiconductor device according to a first embodiment;

FIG. 2 is a diagram for describing a barrier layer of the semiconductor device according to the first embodiment;

FIGS. 3B are diagrams (part 1) for describing an example of a semiconductor device manufacturing method according to the first embodiment;

FIGS. 4A and 4B are diagrams (part 2) for describing the example of the semiconductor device manufacturing method according to the first embodiment;

FIGS. 5A and 5B are diagrams for describing a second example of the semiconductor device according to the first embodiment;

FIG. 6 is a diagram for describing an example of simulation results for electric field intensity distributions in semiconductor devices;

FIGS. 7A and 7B are diagrams for describing a third example of the semiconductor device according to the first embodiment;

FIGS. 8A and 8B are diagrams for describing another example of the semiconductor device manufacturing method according to the first embodiment;

FIGS. 9A to 9D are diagrams (part 1) for describing electric field intensity distributions in various semiconductor devices;

FIG. 10 is a diagram (part 2) for describing the electric field intensity distributions in the various semiconductor devices;

FIG. 11 is a diagram for describing an example of a barrier layer of a semiconductor device according to a second embodiment;

FIGS. 12A and 12B are diagrams (part 1) for describing an example of a semiconductor device manufacturing method according to the second embodiment;

FIGS. 13A and 13B are diagrams (part 2) for describing the example of the semiconductor device manufacturing method according to the second embodiment;

FIG. 14 is a diagram for describing an example of a semiconductor package according to a third embodiment;

FIG. 15 is a diagram for describing an example of a power factor correction circuit according to a fourth embodiment;

FIG. 16 is a diagram for describing an example of a power supply device according to a fifth embodiment; and

FIG. 17 is a diagram for describing an example of an amplifier according to a sixth embodiment.

### DESCRIPTION OF EMBODIMENTS

A semiconductor device may suffer performance degradation due to a phenomenon caused by a configuration of a region where electrodes are provided, for example, due to electric field concentration at an edge of a gate electrode on a drain electrode side when a high voltage is applied to the drain electrode.

### First Embodiment

First, a first example of a semiconductor device according to a first embodiment will be described.

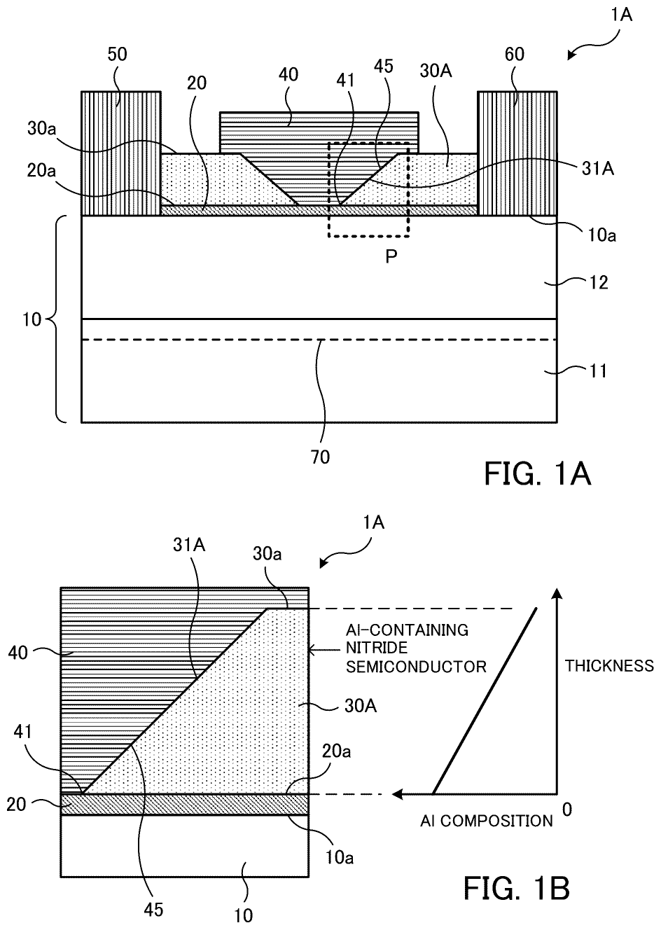

FIGS. 1A and 1B are diagrams for describing a first example of the semiconductor device according to the first embodiment. FIG. 1A schematically illustrates a cross-sectional view of a main part of the example of the semiconductor device. FIG. 1B illustrates an enlarged view of a portion P in FIG. 1A and an example of the relationship between the thickness of a barrier layer and aluminum (Al) composition.

The semiconductor device 1A illustrated in FIGS. 1A and 1B is an example of a semiconductor device including a high electron mobility transistor (HEMT). The semiconductor device 1A includes a substrate 10, an insulating film 20, a barrier layer 30A, a gate electrode 40, a source electrode 50, and a drain electrode 60.

The substrate 10 includes an electron transit layer 11 and an electron supply layer 12.

A nitride semiconductor, for example, gallium nitride (GaN), which is a nitride of gallium (Ga), is used for the electron transit layer 11. Instead of GaN, a nitride semiconductor such as aluminum gallium nitride (AlGaN) or indium gallium nitride (InGaN) may be used for the electron transit layer 11.

AlGaN is obtained by partially substituting Ga in GaN with aluminum (Al), and may be referred to as a nitride of Ga containing Al. InGaN is obtained by partially substituting Ga in GaN with indium (In), and may be referred to as a nitride of Ga containing In.

The electron transit layer 11 may be formed on a predetermined base substrate, not illustrated, by, for example, metal organic chemical vapor deposition (MOCVD), metal organic vapor phase epitaxy (MOVPE), molecular beam epitaxy (MBE), or another. For the base substrate on which the electron transit layer 11 is formed, various substrates such as silicon carbide (SiC), GaN, silicon (Si), sapphire, and diamond are used.

A nitride semiconductor such as AlGaN is used for the electron supply layer 12. Instead of AlGaN, a nitride semiconductor such as indium aluminum gallium nitride (InAlGaN) or indium aluminum nitride (InAlN) may be used for the electron supply layer 12.

InAlGaN is obtained by partially substituting Ga in GaN with In and Al, and may be referred to as a nitride of Ga containing In and Al. In addition, InAlN is obtained by partially substituting Al in AlN with In, and may be referred to as a nitride of Al containing In.

The electron supply layer 12 is provided on one surface side of the electron transit layer 11, for example, on the group III polar surface side thereof. The electron supply layer 12 is formed on the one surface of the electron transit layer 11 using the MOCVD method or another.

Here, nitride semiconductors having different band gaps are used for the electron transit layer 11 and the electron supply layer 12. A nitride semiconductor with a larger band gap is used for the electron supply layer 12 than for the electron transit layer 11. A two-dimensional electron gas (2DEG) region 70 is formed in the electron transit layer 11 by the spontaneous polarization of the nitride semiconductor forming the electron supply layer 12 and the piezoelectric polarization generated in the electron supply layer 12 due to strain caused by the lattice constant difference between the nitride semiconductor forming the electron transit layer 11 and the nitride semiconductor forming the electron supply layer 12. For the electron transit layer 11 and the electron supply layer 12, nitride semiconductors that, in combination, form the 2DEG region 70 in the electron transit layer 11 are used.

Although not illustrated, a layer of AlN or the like may be provided as an initial layer, a layer of AlGaN or the like may be provided as a buffer layer, or a layer of GaN or the like doped with iron (Fe) may be provided between the electron transit layer 11 and the base substrate on which the electron transit layer 11 is formed. In addition, a layer of AlN, AlGaN, or the like may be provided as a back barrier layer for quantum confinement between the electron transit layer 11 and the base substrate. A layer of AlGaN, InGaN, or the like may be provided as a spacer layer between the electron transit layer 11 and the electron supply layer 12. A layer of GaN or the like may be provided as a cap layer on the side of the electron supply layer 12 opposite to the electron transit layer 11. The substrate 10 of the semiconductor device 1A may include, in addition to the electron transit layer 11 and the electron supply layer 12, one or more of the above initial layer, buffer layer, spacer layer, back barrier layer, cap layer, and others.

As illustrated in FIGS. 1A and 1B, the insulating film 20 is provided on the one surface 10a side of the substrate 10. The surface 10a of the substrate 10 is also referred to as a “first surface”. In the example of FIGS. 1A and 1B, the surface 10a of the substrate 10 is the surface of the electron supply layer 12 opposite to the electron transit layer 11.

Various insulating materials are used for the insulating film 20. As an example, the insulating film 20 includes silicon nitride (SiN). In this case, SiN in the insulating film 20 may contain an element such as hydrogen (H). For example, amorphous SiN (also referred to as “a-SiN”) containing H at a concentration of 0.6×10²²/cm³ or less is used as SiN in the insulating film 20.

The insulating film 20 including a-SiN containing H is formed on the surface 10a side of the substrate 10 by low pressure chemical vapor deposition (LPCVD), MOCVD, or another. The thickness of the insulating film 20 is set to, for example, 5 nm or less. The density of the insulating film 20 is set to, for example, 2.8 g/cm³ or more.

The insulating film 20 is provided between the substrate 10 and the gate electrode 40, and functions as a gate insulating film. In addition, the insulating film 20 functions as an etching stopper when the barrier layer 30A is etched to form an opening 31A in which the gate electrode 40 is provided.

As illustrated in FIGS. 1A and 1B, the barrier layer 30A is provided on the surface 20a side of the insulating film 20 opposite to the substrate 10. The barrier layer 30A provided on the surface 20a side of the insulating film 20 may also be said to be the barrier layer 30A provided on the surface 10a side of the substrate 10. Hereinafter, the insulating film 20 side or the surface 20a side of the insulating film 20 is also referred to as the substrate 10 side or the surface 10a side of the substrate 10.

The barrier layer 30A is provided with the opening 31A extending from a surface 30a thereof located opposite to the insulating film 20 (or the substrate 10) to reach the insulating film 20. The opening 31A has a shape in which the opening width decreases in a direction from the surface 30a toward the insulating film 20. The insulating film 20 functions as the etching stopper when the opening 31A is formed by etching.

A nitride semiconductor, for example, a nitride semiconductor containing Al (Al-containing nitride semiconductor) is used for the barrier layer 30A. Al contained in the barrier layer 30A is also referred to as a “first element”. An amorphous nitride semiconductor is used for the barrier layer 30A. As illustrated in FIG. 1B, a nitride semiconductor having a graded Al composition in which the Al content decreases in a direction from the insulating film 20 (or the substrate 10) toward the surface 30a, is used for the barrier layer 30A. As an example, amorphous AlGaN (also referred to as “a-AlGaN”) having a graded Al composition in which the Al content decreases in the direction from the insulating film 20 toward the surface 30a is used for the barrier layer 30A. Instead of a-AlGaN, a nitride semiconductor such as amorphous InAlGaN or InAlN having a graded Al composition may be used for the barrier layer 30A.

As will be described later, the opening 31A of the barrier layer 30A is formed by forming a through hole by dry etching using chlorine (Cl)-based gas and then performing wet etching using potassium hydroxide (KOH).

Here, as described above, a nitride semiconductor such as a-AlGaN having a graded Al composition is used for the barrier layer 30A. In a nitride semiconductor having a graded Al composition, the etching rate is higher in a region having a low Al composition than in a region having a high Al composition during wet etching using KOH. Therefore, in the barrier layer 30A formed using a nitride semiconductor having a graded Al composition in which the Al content decreases toward the surface 30a, the opening 31A whose opening width decreases in the direction from the surface 30a toward the insulating film 20 is formed by the wet etching using KOH.

As illustrated in FIGS. 1A and 1B, the gate electrode 40 is provided in the opening 31A of the barrier layer 30A. It is also said that the gate electrode 40 is provided on the surface 20a side of the insulating film 20 or the surface 10a side of the substrate 10. The opening 31A of the barrier layer 30A has a shape in which the opening width increases in the direction from the insulating film 20 toward the surface 30a. The gate electrode 40 provided in the opening 31A has a shape in which the width increases in the direction from the insulating film 20 toward the surface 30a. It is also said that the gate electrode 40 has a slant structure or a slant gate electrode structure. The gate electrode 40 may be shaped so that the gate electrode 40 is partially provided in the opening 31A and is partially provided on the surface 30a.

Metal materials are used for the gate electrode 40. For example, a stack of nickel (Ni) and gold (Au) provided thereon is used for the gate electrode 40. The gate electrode 40 is formed using a vapor deposition method or another. The gate electrode 40 is provided on the surface 10a side of the substrate 10 with the insulating film 20 such as a-SiN therebetween. The insulating film 20 functions as the gate insulating film. The gate electrode 40 has a metal insulator semiconductor (MIS) gate structure. The MIS gate structure prevents generation of a gate leakage current, which flows from the gate electrode 40 to the substrate 10.

As illustrated in FIGS. 1A and 1B, the source electrode 50 and the drain electrode 60 are provided on both sides of the gate electrode 40 on the surface 10a side of the substrate 10. Metal materials are used for the source electrode 50 and the drain electrode 60. For example, a stack of tantalum (Ta) or titanium (Ti) and Al provided thereon is used for the source electrode 50 and the drain electrode 60. The source electrode 50 and the drain electrode 60 are formed using the vapor deposition method or another.

For example, the source electrode 50 and the drain electrode 60 penetrate through the barrier layer 30A and the insulating film 20, and are connected to the substrate 10. For example, the source electrode 50 and the drain electrode 60 may be connected to the electron supply layer 12 of the substrate 10, or may penetrate through the electron supply layer 12 and then be connected to the electron transit layer 11. A contact layer (regrown layer) using a nitride semiconductor such as n-type GaN or n-type AlGaN may be provided at portions to which the source electrode 50 and the drain electrode 60 are connected, on the electron supply layer 12 or the electron transit layer 11.

In order to increase the breakdown voltage of the semiconductor device 1A, the gate electrode 40 may be provided closer to the source electrode 50 than to the drain electrode 60, that is, the gate electrode 40 may be disposed asymmetrically.

During operation of the semiconductor device 1A having the above configuration, a predetermined voltage (potential difference) is applied between the source electrode 50 and the drain electrode 60, and a predetermined voltage (gate voltage) is applied to the gate electrode 40. The amount of charge passing through the 2DEG region 70 directly below the gate electrode 40 between the source electrode 50 and the drain electrode 60 is controlled by the field effect of the voltage applied to the gate electrode 40, so that the drain current to be output is controlled. In this way, the transistor function of the semiconductor device 1A is achieved.

In the semiconductor device 1A, the gate electrode 40 is provided in the opening 31A of the barrier layer 30A whose opening width increases in the direction from the insulating film 20 toward the surface 30a. Thus, the gate electrode 40 has a slant structure in which the width increases in the direction from the insulating film 20 toward the surface 30a. The gate electrode 40 having the slant structure has a shape in which a surface (also referred to as an “inclined surface”) 45 facing the surface 20a of the insulating film 20 (or the surface 10a of the substrate 10) via the barrier layer 30A extends toward the drain electrode 60 as it moves away from the surface 20a (or the surface 10a), starting from a portion in contact with the insulating film 20. Since the gate electrode 40 or the opening 31A in which the gate electrode 40 is provided has such a shape, it is possible to prevent an electric field having a relatively high intensity from being intensively applied to the vicinity of an edge (also referred to as a “drain-side edge”) 41 of the gate electrode 40 closer to the drain electrode 60 during the operation of the semiconductor device 1A.

In general, during operation of a semiconductor device, a relatively high voltage is applied to the drain electrode side. In this case, a phenomenon in which an electric field having a relatively high intensity may be intensively applied, that is, so-called electric field concentration may occur in the vicinity of the drain-side edge of the gate electrode. If the electric field intensity at the drain-side edge of the gate electrode exceeds the limit of the material in the vicinity of the drain-side edge due to the electric field concentration, breakdown may occur in the semiconductor device.

By contrast, in the semiconductor device 1A having the above-described configuration, the gate electrode 40 having the slant structure in which the width increases in the direction from the insulating film 20 toward the surface 30a of the barrier layer 30A is provided. This relaxes the electric field concentration in the vicinity of the drain-side edge 41 of the gate electrode 40. This in turn prevents the electric field in the material in the vicinity of the drain-side edge 41 from reaching the breakdown electric field, thereby preventing the breakdown in the semiconductor device 1A. As a result, the high-performance semiconductor device 1A is achieved, which is capable of minimizing its performance degradation that is caused by breakage.

In addition, in general, when a gate voltage is applied in a forward bias (+ direction) while a semiconductor device having a Schottky gate structure operates, a phenomenon in which a current leaks from the gate electrode toward the source electrode, that is, a so-called gate leakage current may occur. If such a gate leakage current occurs in the semiconductor device, the maximum drain current may decrease.

By contrast, in the semiconductor device 1A having the above-described configuration, the insulating film 20 such as a-SiN is interposed between the gate electrode 40 and the substrate 10. Thus, during the operation of the semiconductor device 1A, the occurrence of the gate leakage current is suppressed, and the decrease in the maximum drain current due to the gate leakage current is prevented. Therefore, the high-performance semiconductor device 1A is achieved, which is capable of minimizing its performance degradation that is caused by the gate leakage current.

According to the above configuration, the high-performance semiconductor device 1A is achieved, which is capable of minimizing its performance degradation that is caused by the electric field concentration and gate leakage current.

Here, the barrier layer 30A will be described.

In the semiconductor device 1A described above, the barrier layer 30A is considered to have the following configuration.

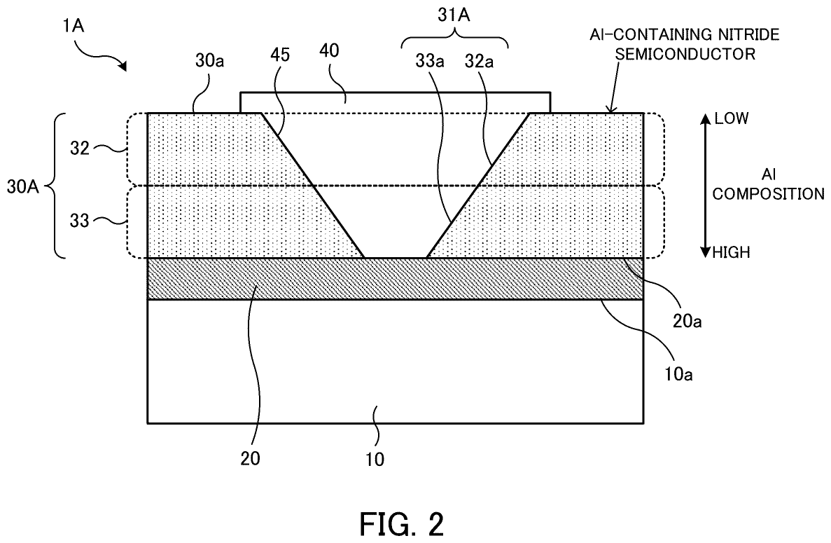

FIG. 2 is a diagram for describing the barrier layer of the semiconductor device according to the first embodiment. FIG. 2 schematically illustrates a cross-sectional view of a main part in the vicinity of the opening of the barrier layer.

As described above, in the semiconductor device 1A, the insulating film 20 is provided on the surface 10a side of the substrate 10, and the barrier layer 30A is provided on the surface 20a side of the insulating film 20. The barrier layer 30A is provided so as to have a graded Al composition in which the Al content decreases in the direction from the insulating film 20 toward the surface 30a. For example, the barrier layer 30A is a layer of a-AlGaN having such a graded Al composition. The barrier layer 30A having the graded Al composition is formed by adjusting the supply amount of the Al raw material (trimethylaluminum or another) continuously or stepwise so that the amount decreases toward the surface 30a during the growth of a-AlGaN or another using the MOCVD method.

Alternatively, the barrier layer 30A may also be considered to have a configuration in which a plurality of layers are stacked in the thickness direction. In FIG. 2, for convenience of description, the barrier layer 30A is illustrated as having a configuration in which two layers, a first layer 32 and a second layer 33 of a-AlGaN or the like, are stacked in order from the surface 30a side. That is, each of the first layer 32 and the second layer 33 is a part of the barrier layer 30A. For example, the barrier layer 30A is formed such that the Al concentrations (Al amounts per unit volume) of the first layer 32 and the second layer 33 have a relationship of the first layer 32 <the second layer 33.

Here, the Al compositions of the first layer 32 and the second layer 33 may be set so that the Al content is constant in each layer. Alternatively, each of the first layer 32 and the second layer 33 does not need to have an Al composition in which the Al content is constant, and may be set to have a graded Al composition in which the Al content decreases toward the surface 30a. In the case where the Al compositions of the first layer 32 and the second layer 33 of the barrier layer 30A are set in this manner, the Al concentrations of the first layer 32 and the second layer 33 have a relationship of the first layer 32<the second layer 33.

The first layer 32 and the second layer 33 have a first opening 32a and a second opening 33a, respectively. The first opening 32a and the second opening 33a communicate with each other. Each of the first opening 32a and the second opening 33a is a part of the opening 31A of the barrier layer 30A. The opening widths of the first opening 32a and the second opening 33a have a relationship of the first opening 32a >the second opening 33a.

Here, in the barrier layer 30A, the Al composition decreases in the direction from the insulating film 20 toward the surface 30a. Therefore, during wet etching using KOH, the etching rate increases in the direction from the insulating film 20 toward the surface 30a. Therefore, the opening widths of the first opening 32a and the second opening 33a formed by the wet etching using KOH have a relationship of the first opening 32a>the second opening 33a.

From such a viewpoint, the barrier layer 30A may be regarded as having a configuration including the first layer 32 and the second layer 33 containing Al as the first element at different concentrations. Here, the first layer 32 is a layer that is provided on the surface 10a side of the substrate 10, contains Al at a first concentration, and has the first opening 32a. The second layer 33 is a layer that is provided between the surface 10a of the substrate 10 and the first layer 32, contains Al at a second concentration higher than the first concentration, and has the second opening 33a communicating with the first opening 32a of the first layer 32 and having a smaller opening width than the first opening 32a.

The second layer 33 before the second opening 33a is formed is also referred to as a “third layer”, and the first layer 32 before the first opening 32a is formed is also referred to as a “fourth layer”. By the wet etching using KOH, the first opening is formed in the fourth layer, thereby forming the first layer, and the second opening is formed in the third layer, thereby forming the second layer.

In FIG. 2, for convenience, the barrier layer 30A has been described as including two layers, the first layer 32 and the second layer 33, but the number of layers included in the barrier layer 30A is not limited to two, and may be three or more. Even in the case where the barrier layer 30A includes three or more layers, it may be considered that any two of the three or more layers have the same relationship as that of the first layer 32 and the second layer 33.

The following describes an example of a method of manufacturing the above-described semiconductor device 1A.

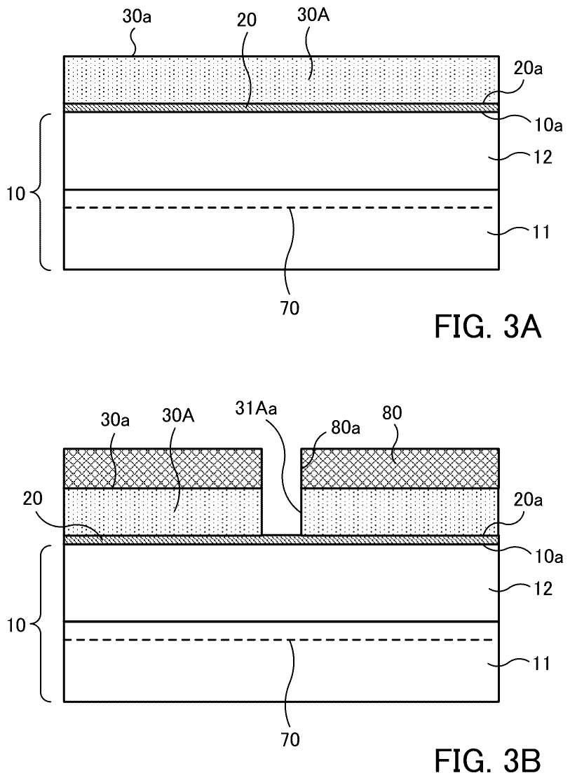

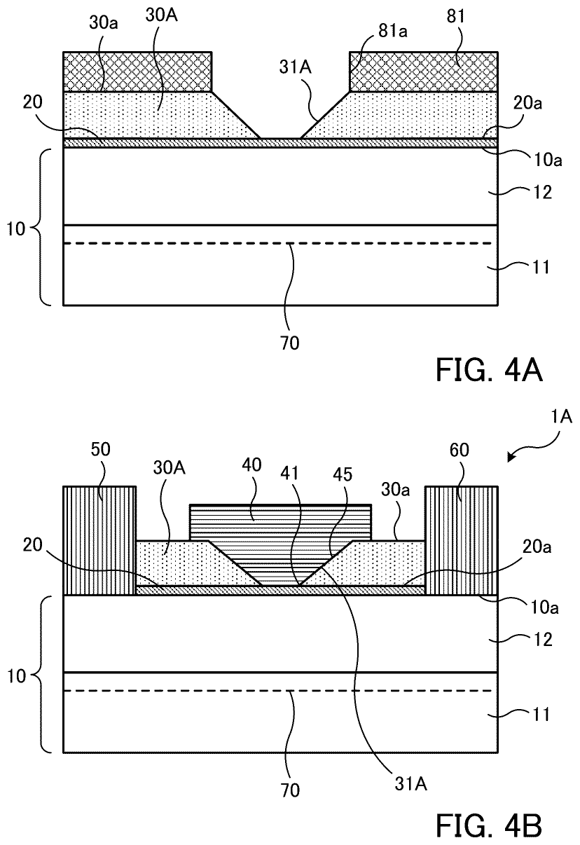

FIGS. 3A, 3B, 4A, and 4B are diagrams for describing an example of a semiconductor device manufacturing method according to the first embodiment. FIGS. 3A and 3B and FIGS. 4A and 4B each schematically illustrate a cross-sectional view of a main part in the example of the semiconductor device manufacturing process.

First, a structure as illustrated in FIG. 3A, that is, a structure in which the barrier layer 30A is formed on the substrate 10 with the insulating film 20 therebetween is formed.

The substrate 10 is formed by growing the electron transit layer 11, the electron supply layer 12, and others on a predetermined base substrate (not illustrated) using the MOCVD method or the like. For example, GaN is formed as the electron transit layer 11, and AlGaN is formed as the electron supply layer 12. The thickness of the electron transit layer 11 is set in the range of 100 nm to 200 nm, for example. The thickness of the electron supply layer 12 is set in the range of 5 nm to 30 nm, for example. In addition to the electron transit layer 11 and the electron supply layer 12, one or more of an initial layer, a buffer layer, a spacer layer, a back barrier layer, a cap layer, and others may be formed using predetermined nitride semiconductors in obtaining the substrate 10.

The insulating film 20 is formed on the surface 10a of the substrate 10 using the LPCVD method, the MOCVD method, or another. For example, a-SiN is formed as the insulating film 20. In the formation of a-SiN using the LPCVD method or the MOCVD method, for example, the formation temperature is set in the range of 780° C. to 850° C. As a result, as the insulating film 20, a-SiN containing H at a concentration of 0.6×10²²/cm³ or less with a density of 2.8 g/cm³ or more is formed. The etching rate of such a-SiN with respect to Cl-based gas is about 1/10 of the etching rate of a-AlGaN of the barrier layer 30A, which is formed as described below, with respect to Cl-based gas. The thickness of the insulating film 20 is set to 5 nm or less, for example, in the range of 4 nm to 5 nm.

The barrier layer 30A is formed on the surface 20a of the insulating film 20 using the MOCVD method or another. For example, a-AlGaN having a graded Al composition in which the Al content decreases in the direction from the insulating film 20 (the substrate 10) toward the surface 30a of the barrier layer 30A is formed as the barrier layer 30A. The a-AlGaN having the graded Al composition is formed by adjusting the supply amount of the Al raw material (trimethylaluminum or another) continuously or stepwise during growth such that the amount decreases toward the surface 30a of the barrier layer 30A. The thickness of the barrier layer 30A is set in the range of 10 nm to 100 nm, for example.

After the structure in which the barrier layer 30A is formed on the substrate 10 with the insulating film 20 therebetween is formed, a resist 80 having an opening 80a in a region where the gate electrode 40 is to be formed is formed on the barrier layer 30A, as illustrated in FIG. 3B. Using the resist 80 as a mask, dry etching using Cl-based gas is performed on the barrier layer 30A through the opening 80a. Thus, as illustrated in FIG. 3B, a through hole 31Aa reaching the insulating film 20 is formed in the barrier layer 30A. The insulating film 20 has a lower etching rate with respect to Cl-based gas than the barrier layer 30A. Therefore, the insulating film 20 functions as an etching stopper when the through hole 31Aa is formed in the barrier layer 30A by the dry etching as described above. After the through hole 31Aa is formed, the resist 80 is removed.

After the through hole 31Aa of the barrier layer 30A is formed, a resist 81 having an opening 81a in a region including the through hole 31Aa and the periphery thereof (the periphery located closer to the regions where the source electrode 50 and the drain electrode 60 are to be formed) is formed on the barrier layer 30A, as illustrated in FIG. 4A. Using the resist 81 as a mask, wet etching using KOH is performed on the barrier layer 30A through the opening 81a. The opening width of the through hole 31Aa of the barrier layer 30A is widened by the wet etching. In the barrier layer 30A having the graded Al composition, the etching rate is higher in a region having a low Al composition (Al concentration) than in a region having a high Al composition in the wet etching using KOH. Therefore, as illustrated in FIG. 4A, in the barrier layer 30A having the graded Al composition in which the Al content decreases toward the surface 30a, the opening 31A whose opening width decreases in the direction from the surface 30a toward the insulating film 20 is formed by the wet etching using KOH. After the opening 31A is formed, the resist 81 is removed.

It may also be said that, for the barrier layer 30A, the first layer 32 having the first opening 32a and the second layer 33 having the second opening 33a as described with reference to FIG. 2 are formed by such wet etching using KOH. In this case, in the barrier layer 30A before the wet etching, the second layer 33 before the second opening 33a is formed may be referred to as the “third layer”, and the first layer 32 before the first opening 32a is formed may be referred to as the “fourth layer”.

After the opening 31A of the barrier layer 30A is formed, the gate electrode 40, the source electrode 50, and the drain electrode 60 are formed as illustrated in FIG. 4B.

For example, the barrier layer 30A and the insulating film 20 are etched to remove regions where the source electrode 50 and the drain electrode 60 are to be formed, and a stack of Ta or Ti and Al is deposited in each region using the vapor deposition method, thereby forming the source electrode 50 and the drain electrode 60.

In addition, a stack of Ni and Au is deposited in the opening 31A of the barrier layer 30A using the vapor deposition method, thereby forming the gate electrode 40. The opening 31A of the barrier layer 30A has a shape in which the opening width increases in the direction from the insulating film 20 toward the surface 30a. The gate electrode 40 formed in the opening 31A has a slant structure in which the width increases in the direction from the insulating film 20 toward the surface 30a. That is, the gate electrode 40 having the slant structure is formed in which the inclined surface 45 of the gate electrode 40 facing the surface 20a of the insulating film 20 via the barrier layer 30A extends toward the source electrode 50 and the drain electrode 60 as it moves away from the surface 20a.

Through the above-described process, the semiconductor device 1A as illustrated in FIG. 4B is manufactured, for example.

In this connection, the source electrode 50 and the drain electrode 60 may be formed on the surface 10a of the substrate 10 after the formation of the substrate 10 and before the formation of the insulating film 20 and the barrier layer 30A. In this case, the insulating film 20 and the barrier layer 30A are formed on the surface 10a of the substrate 10 on which the source electrode 50 and the drain electrode 60 are formed, in the same way as the example of FIG. 3A. At this time, the insulating film 20 and the barrier layer 30A may be formed so as to cover the source electrode 50 and the drain electrode 60 on the surface 10a of the substrate 10. Alternatively, the source electrode 50 and the drain electrode 60 may be formed after the formation of the substrate 10 and the insulating film 20 and before the formation of the barrier layer 30A. In this case, the source electrode 50 and the drain electrode 60 are formed on the surface 10a of the substrate 10 from which a part of the insulating film 20 is removed, and then the barrier layer 30A is formed in the same way as the example of FIG. 3A. In this case, the barrier layer 30A may be formed to cover the source electrode 50 and the drain electrode 60. Thereafter, the through hole 31Aa is formed in the same way as the example of FIG. 3B, the opening 31A is formed in the same way as the example of FIG. 4A, and the gate electrode 40 is formed in the same way as the example of FIG. 4B. The semiconductor device 1A may be manufactured in this manner.

In order to form the gate electrode 40 having the slant structure, the following method is also considered: a barrier layer formed on the insulating film 20 on the substrate 10 is ablated using a yttrium aluminum garnet (YAG) laser or the like to form an opening whose opening width increases in a direction from the insulating film 20 toward the front surface of the barrier layer. However, this method needs a long time for the ablating using the YAG laser or another, which may significantly reduce the productivity of the semiconductor device including the gate electrode 40 having the slant structure.

By contrast, in the above-described method of manufacturing the semiconductor device 1A, a barrier layer having a graded Al composition in which the Al content decreases in the direction from the insulating film 20 toward the surface 30a is formed as the barrier layer 30A. Then, using the fact that the etching rate is higher in a region having a low Al composition (Al concentration) than in a region having a high Al composition in wet etching using KOH, the opening 31A whose opening width decreases in the direction from the surface 30a toward the insulating film 20 is formed by wet etching. The insulating film 20 functions as an etching stopper during the wet etching and during the dry etching performed prior to the wet etching. The gate electrode 40 is formed in the opening 31A formed in this way in the barrier layer 30A. The gate electrode 40 formed in the opening 31A has a slant structure.

With the above-described method of manufacturing the semiconductor device 1A using the etching, it is possible to manufacture, with high productivity, the semiconductor device 1A that includes the gate electrode 40 having the slant structure and is capable of suppressing electric field concentration in the vicinity of the drain-side edge 41 and thus preventing breakdown due to the electric field concentration. The insulating film 20 used as the etching stopper may also be used as a gate insulating film. Therefore, with the above-described method of manufacturing the semiconductor device 1A, it is possible to manufacture, with high productivity, the semiconductor device 1A that is capable of suppressing the occurrence of the gate leakage current and thus preventing the decrease in the maximum drain current due to the gate leakage current.

With the above-described manufacturing method, it is possible to efficiently manufacture the high-performance semiconductor device 1A that is capable of minimizing its performance degradation that is caused by electric field concentration and gate leakage current.

The following describes a second example of the semiconductor device according to the first embodiment.

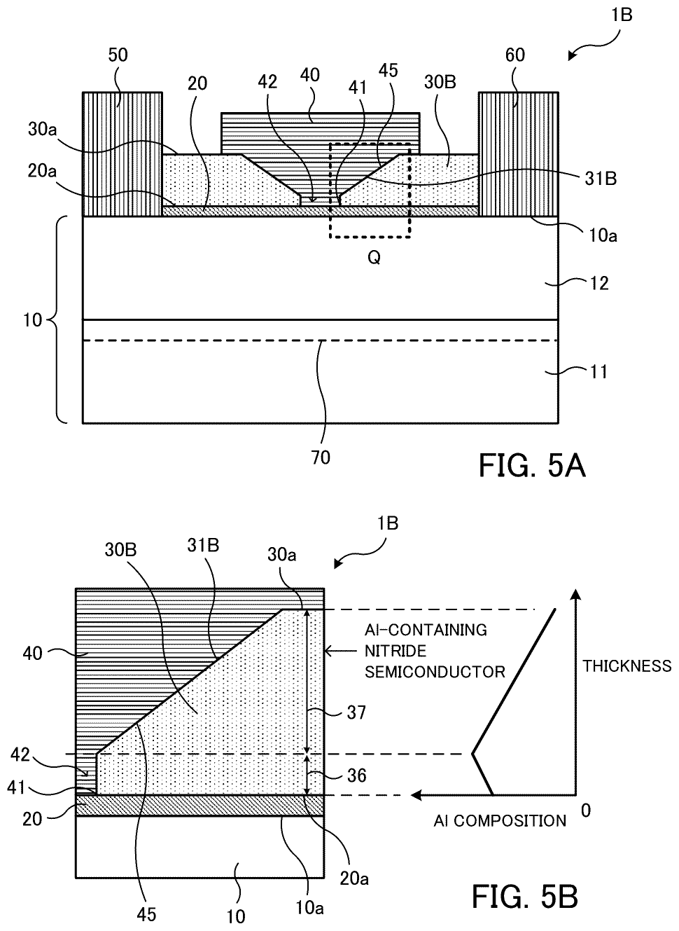

FIGS. 5A and 5B are diagrams for describing the second example of the semiconductor device according to the first embodiment. FIG. 5A schematically illustrates a cross-sectional view of a main part of the example of the semiconductor device. FIG. 5B illustrates an enlarged view of a portion Q in FIG. 5A and an example of the relationship between the thickness of a barrier layer and Al composition.

In the semiconductor device 1B illustrated in FIGS. 5A and 5B, the gate electrode 40 has a portion (also referred to as a “rising portion”) 42 extending so as to rise from the surface 20a of the insulating film 20. In the gate electrode 40 of the semiconductor device 1B, the inclined surface 45 facing the surface 20a of the insulating film 20 (or the surface 10a of the substrate 10) via a barrier layer 30B extends from the rising portion 42 toward the source electrode 50 and the drain electrode 60 as it moves away from the surface 20a (or the surface 10a). The semiconductor device 1B is different from the semiconductor device 1A (FIGS. 1A and 1B) in that the semiconductor device 1B includes the gate electrode 40 having such a shape.

The semiconductor device 1B includes the barrier layer 30B having an opening 31B in which the gate electrode 40 having the shape as illustrated in FIGS. 5A and 5B is provided. The barrier layer 30B has a portion 36 in which the rising portion 42 of the gate electrode 40 is provided. The barrier layer 30B further has a portion 37 in which the inclined surface 45 of the gate electrode 40 facing the surface 20a of the insulating film 20 via the barrier layer 30B extends toward the source electrode 50 and the drain electrode 60 as it moves away from the surface 20a. As illustrated in FIG. 5B, a nitride semiconductor such as a-AlGaN is formed for the portion 36 so as to have a relatively high Al composition. For the portion 37, a nitride semiconductor such as a-AlGaN is formed so as to have a graded Al composition as in the barrier layer 30A. That is, as illustrated in FIG. 5B, the nitride semiconductor such as a-AlGaN is formed such that the portion 37 has a graded Al composition in which the Al content at the boundary with the rising portion 42 is the maximum value and the Al content decreases in the direction from the insulating film 20 toward the surface 30a.

The opening 31B of the barrier layer 30B is formed by performing wet etching using KOH after dry etching, in the same way as the example (FIG. 3B, FIG. 4A, and others) described for the formation of the opening 31A of the barrier layer 30A. In the wet etching using KOH, the etching rate is higher in a region having a low Al composition (Al concentration) than in a region having a high Al composition. Therefore, in the barrier layer 30B having the Al composition as described above, an opening in which its opening width decreases in the direction from the surface 30a toward the insulating film 20 is formed in the portion 37. An opening is formed in the portion 36 so as to extend to the insulating film 20 with its opening width substantially equal to the opening width at the boundary with the portion 37. The relatively high Al composition at the boundary between the portion 36 and the portion 37 prevents the opening of the portion 36 from being widened. Thus, the opening 31B having the shape illustrated in FIGS. 5A and 5B is formed.

In the semiconductor device 1B, the gate electrode 40 is formed in the opening 31B of the barrier layer 30B having the above-described shape. Thus, the gate electrode 40 is formed that has the rising portion 42 on the surface 20a of the insulating film 20 and extends from the rising portion 42 toward the source electrode 50 and the drain electrode 60 as it moves away from the surface 20a of the insulating film 20.

In this connection, the barrier layer 30B of the semiconductor device 1B is considered to have a configuration including at least a “first layer” and a “second layer” containing Al as the first element at different concentrations, from the same viewpoint as described with reference to FIG. 2. Here, the first layer is a layer that is provided on the surface 10a side of the substrate 10, contains Al at a first concentration, and has a “first opening”. The second layer is a layer that is provided between the surface 10a of the substrate 10 and the first layer, contains Al at a second concentration higher than the first concentration, and has a “second opening” communicating with the first opening of the first layer and having a smaller opening width than the first opening. The second layer before the second opening is formed is the “third layer”, and the first layer before the first opening is formed is the “fourth layer”.

The following describes results of simulating the electric field intensity in the semiconductor device 1A described in the first example and the semiconductor device 1B described in the second example.

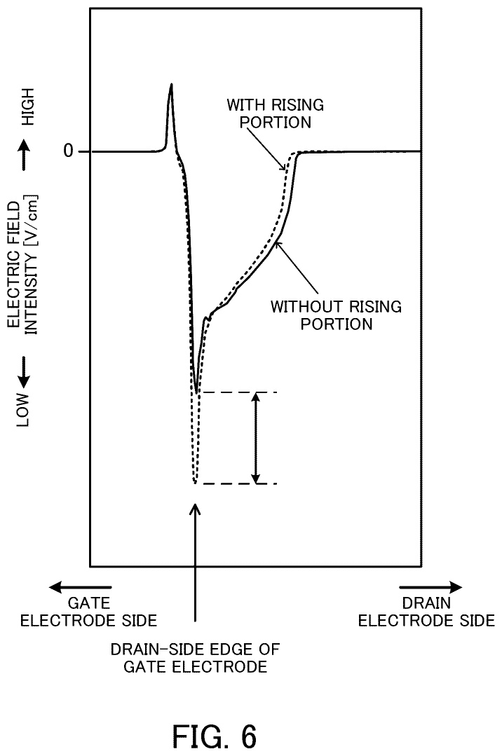

FIG. 6 is a diagram for describing an example of simulation results for the electric field intensity distributions in the semiconductor devices.

FIG. 6 illustrates an example of the simulation results for the electric field intensity distribution when a voltage (drain voltage) Vd to be applied to the drain electrode 60 is set to 50 V and a voltage (gate voltage) Vg to be applied to the gate electrode 40 is set to −5 V. In FIG. 6, the electric field intensity distribution of the semiconductor device 1A in which the gate electrode 40 does not have the rising portion 42 is represented by a solid line (indicated as “without rising portion”), and the electric field intensity distribution of the semiconductor device 1B in which the gate electrode 40 has the rising portion 42 is represented by a dotted line (indicated as “with rising portion”).

As illustrated in FIG. 6, the semiconductor device 1A (“without rising portion” represented by the solid line) has a reduced electric field concentration at the position corresponding to the drain-side edge 41 of the gate electrode 40, as compared with the semiconductor device 1B (“with rising portion” represented by the dotted line). Therefore, it is preferable to reduce the height of the rising portion 42 of the gate electrode 40 (the height measured from the surface 20a of the insulating film 20) from the viewpoint of suppressing the electric field concentration at the position corresponding to the drain-side edge 41 of the gate electrode 40.

The following describes a third example of the semiconductor device according to the first embodiment.

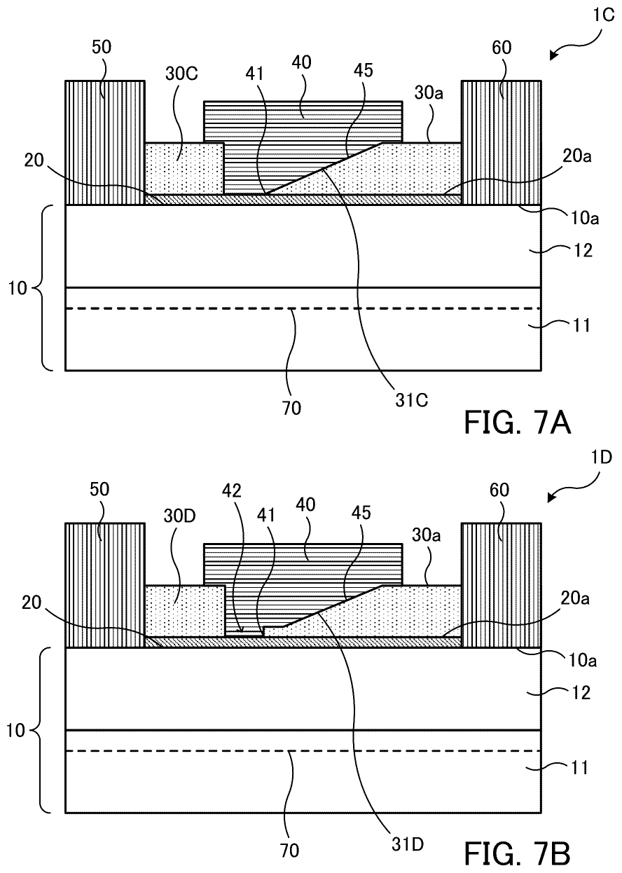

FIGS. 7A and 7B are diagrams for describing a third example of the semiconductor device according to the first embodiment. FIGS. 7A and 7B each schematically illustrate a cross-sectional view of a main part of the example of the semiconductor device.

The semiconductor device 1C illustrated in FIG. 7A includes a gate electrode 40 having a slant structure in which its width increases in the direction from the insulating film 20 toward the surface 30a. In the gate electrode 40 of the semiconductor device 1C, the inclined surface 45 facing the surface 20a of the insulating film 20 via a barrier layer 30C extends toward the drain electrode 60 as it moves away from the surface 20a. The semiconductor device 1C is different from the semiconductor device 1A (FIGS. 1A and 1B) in that the semiconductor device 1C includes the gate electrode 40 having such a shape.

A nitride semiconductor such as a-AlGaN is used for the barrier layer 30C of the semiconductor device 1C. As with the barrier layer 30A, the barrier layer 30C has a graded Al composition in which the Al content decreases in the direction from the insulating film 20 toward the surface 30a. The barrier layer 30C has an opening 31C whose opening width increases in the direction from the insulating film 20 toward the surface 30a. The opening 31C is provided so as to extend from the position on the surface 20a of the insulating film 20 toward the surface 30a and the drain electrode 60 out of the source electrode 50 and the drain electrode 60. The gate electrode 40 is provided in this opening 31C, which has a slant structure extending from the position connected to the surface 20a of the insulating film 20 toward the surface 30a and the drain electrode 60 as illustrated in FIG. 7A.

The semiconductor device 1D illustrated in FIG. 7B is different from the semiconductor device 1C illustrated in FIG. 7A in that the gate electrode 40 has a rising portion 42 extending so as to rise from the surface 20a of the insulating film 20.

A nitride semiconductor such as a-AlGaN is used for a barrier layer 30D of the semiconductor device 1D. The barrier layer 30D has a relatively high Al composition in a region where the rising portion 42 of the gate electrode 40 is provided, and has a graded Al composition in a region above the region. The barrier layer 30D has an opening 31D that extends with its opening width decreasing in the direction from the surface 30a toward the insulating film 20 and then extends to the insulating film 20 with a substantially equal opening width. The gate electrode 40 is provided in this opening 31D, which has the rising portion 42 on the surface 20a of the insulating film 20 and has the slant structure extending from the rising portion 42 toward the surface 30a and the drain electrode 60 as illustrated in FIG. 7B.

The barrier layer 30C of the semiconductor device 1C and the barrier layer 30D of the semiconductor device 1D may each be regarded as having a configuration including at least a “first layer” and a “second layer” containing Al, which is the first element, at different concentrations, from the same viewpoint as described with reference to FIG. 2. Here, the first layer is a layer that is provided on the surface 10a side of the substrate 10, contains Al at a first concentration, and has the “first opening”. The second layer is a layer that is provided between the surface 10a of the substrate 10 and the first layer, contains Al at a second concentration higher than the first concentration, and has the “second opening” communicating with the first opening of the first layer and having a smaller opening width than the first opening. The second layer before the second opening is formed is the “third layer”, and the first layer before the first opening is formed is the “fourth layer”.

The electric field concentration is likely to occur in the vicinity of the drain-side edge 41 of the gate electrode 40. In the semiconductor device 1C and the semiconductor device 1D, the gate electrode 40 is provided so as to extend toward the surface 30a and the drain electrode 60 out of the source electrode 50 and the drain electrode 60. Thus, the semiconductor device 1C and the semiconductor device 1D each have a reduced electric field concentration in the vicinity of the drain-side edge 41 of the gate electrode 40.

In addition, in each of the semiconductor device 1C and the semiconductor device 1D, the gate electrode 40 is provided so as to extend from the position connected to the insulating film 20 toward the drain electrode 60 out of the source electrode 50 and the drain electrode 60. Therefore, as compared with the case where the gate electrode 40 is provided so as to extend toward both the source electrode 50 and the drain electrode 60, it is possible to extend the gate electrode 40 toward the drain electrode 60 while placing the gate electrode 40 closer to the source electrode 50. Alternatively, the distance between the source electrode 50 and the drain electrode 60 disposed so as to have the gate electrode 40 therebetween may be reduced. With the semiconductor device 1C and the semiconductor device 1D, it is possible to realize an asymmetric arrangement of the gate electrode 40 while preventing a size increase, or to achieve a size reduction by narrowing the distance between the source electrode 50 and the drain electrode 60.

The following describes an example of a method of manufacturing the above-described semiconductor device 1C and semiconductor device 1D.

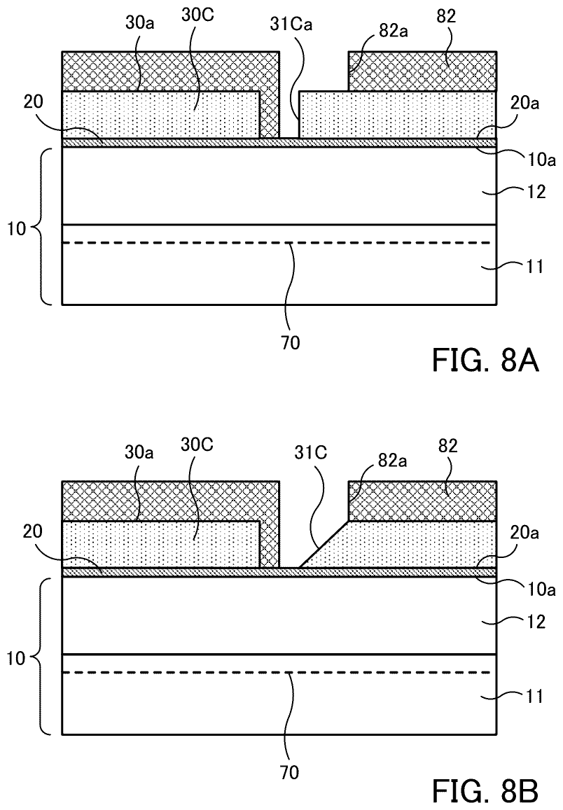

FIGS. 8A and 8B are diagrams for describing another example of the semiconductor device manufacturing method according to the first embodiment. FIGS. 8A and 8B each schematically illustrate a cross-sectional view of a main part in the example of the semiconductor device manufacturing process.

FIGS. 8A and 8B provide a case where the semiconductor device 1C (FIG. 7A) is manufactured, as an example.

In the manufacture of the semiconductor device 1C, a structure in which the barrier layer 30C is formed on the substrate 10 with the insulating film 20 therebetween as illustrated in FIG. 8A is prepared in the same way as the example of FIGS. 3A and 3B described in the manufacture of the semiconductor device 1A (FIG. 1A and others). That is, the structure is prepared in which the insulating film 20 is formed on the surface 10a of the substrate 10, the barrier layer 30C is formed on the surface 20a of the insulating film 20, and the through hole 31Ca is formed in the barrier layer 30C. Then, as illustrated in FIG. 8A, a resist 82 is formed on the barrier layer 30C. More specifically, the resist 82 has an opening 82a in a region including a part of the through hole 31Ca and the periphery thereof (the periphery located closer to the region where the drain electrode 60 is to be formed).

Using the resist 82 as a mask, wet etching using KOH is performed on the barrier layer 30C through the opening 82a. By this wet etching, the opening width of the through hole 31Ca of the barrier layer 30C is widened to one side (toward the region where the drain electrode 60 is to be formed). In the barrier layer 30C having the graded Al composition, the etching rate is higher in a region having a low Al composition (Al concentration) than in a region having a high Al composition in the wet etching using KOH. Therefore, as illustrated in FIG. 8B, in the barrier layer 30C having the graded Al composition in which the Al content decreases toward the surface 30a, the opening 31C whose opening width decreases in the direction from the surface 30a toward the insulating film 20 is formed by the wet etching using KOH. After the opening 31C is formed, the resist 82 is removed.

After the opening 31C of the barrier layer 30C is formed, the source electrode 50 and the drain electrode 60 are formed on the substrate 10 and the gate electrode 40 is formed in the opening 31C of the barrier layer 30C, in the same way as the example of FIG. 4B. Thus, the semiconductor device 1C (FIG. 7A) is manufactured.

The above describes the manufacturing of the semiconductor device 1C as an example. In the case of manufacturing the semiconductor device 1D (FIG. 7B), the barrier layer 30D is formed on the insulating film 20 on the substrate 10. The barrier layer 30D has a relatively high Al composition in a portion where the rising portion 42 of the gate electrode 40 is to be provided, and has a graded Al composition in a portion above the portion. After the barrier layer 30D is formed, a resist 82 having an opening 82a is formed, and the wet etching using KOH is performed to form the opening 31D, by utilizing a difference in etching rate due to the Al composition, in the same way as the example of FIGS. 8A and 8B. Then, the source electrode 50 and the drain electrode 60 are formed on the substrate 10, and the gate electrode 40 is formed in the opening 31D of the barrier layer 30D, in the same way as the example of FIG. 4B. Thus, the semiconductor device 1D is manufactured.

In the manufacture of the semiconductor device 1C and the semiconductor device 1D, the source electrode 50 and the drain electrode 60 may be formed on the surface 10a of the substrate 10 after the formation of the substrate 10 and before the formation of the insulating film 20 and the barrier layer 30C or the barrier layer 30D. Alternatively, the source electrode 50 and the drain electrode 60 may be formed on the surface 10a of the substrate 10 from which a part of the insulating film 20 is removed, after the formation of the substrate 10 and the insulating film 20 and before the formation of the barrier layer 30C or the barrier layer 30D.

The above description provides the example in which a-SiN containing H is used as the insulating film 20. The insulating film 20 of each of the semiconductor devices 1A to 1D is not limited to a-SiN containing H, and any insulating material is also usable as long as it is able to function as both an etching stopper and a gate insulating film.

The following further describes the electric field intensity distributions in various semiconductor devices.

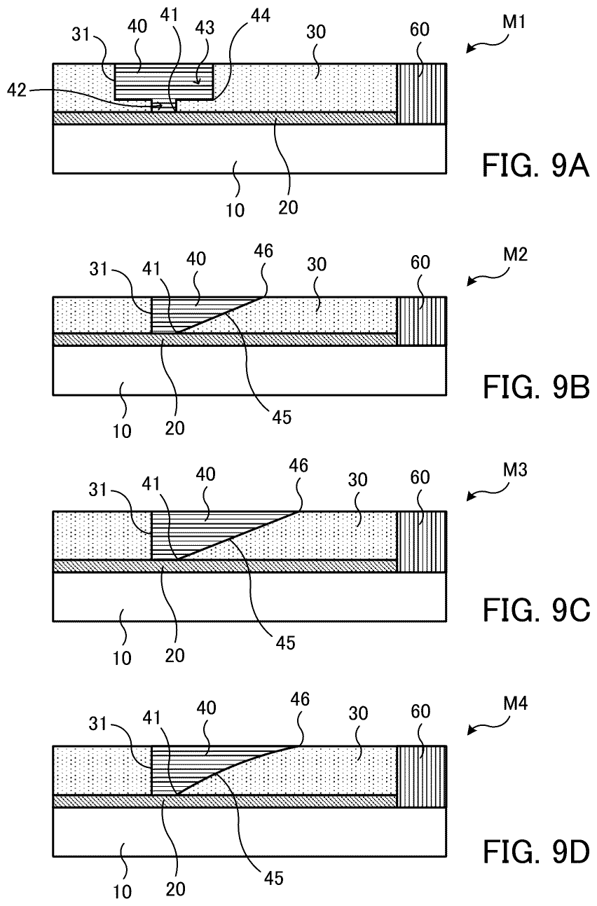

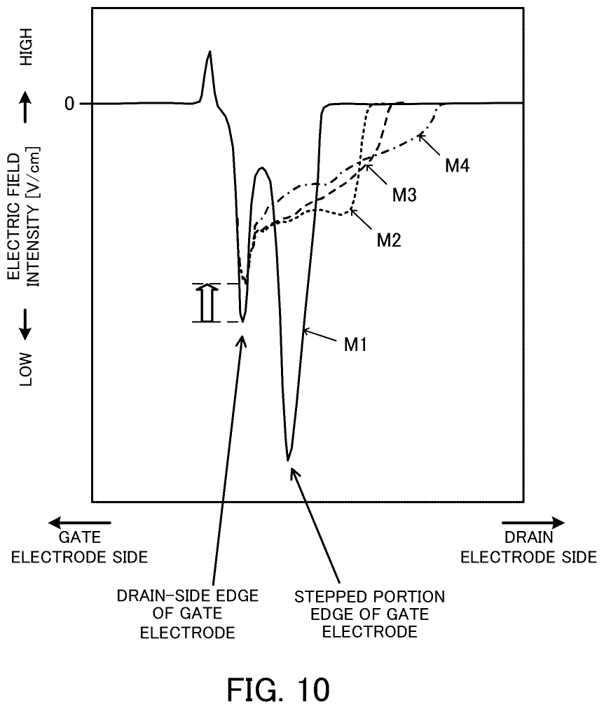

FIGS. 9A to 9D and FIG. 10 are diagrams for describing the electric field intensity distributions in FIGS. 9A to 9D each various semiconductor devices.

illustrate an example of a semiconductor device model. FIG. 10 illustrates an example of the electric field intensity distributions.

For the simulation of the electric field intensity, semiconductor device models M1 to M4 as illustrated in FIGS. 9A to 9D are used. Each of the semiconductor device models M1 to M4 includes a barrier layer 30 and a gate electrode 40 provided on an insulating film 20 on a substrate 10, and a drain electrode 60 provided on the substrate 10. The gate electrode 40 is provided in an opening 31 formed in the barrier layer 30.

The semiconductor device model M1 illustrated in FIG. 9A includes, as the gate electrode 40, a gate electrode having a T-shaped structure including a rising portion 42 extending from the insulating film 20 and a stepped portion 43 facing the insulating film 20 (or the substrate 10) via the barrier layer 30.

The semiconductor device model M2 illustrated in FIG. 9B includes, as the gate electrode 40, a gate electrode having a slant structure in which an inclined surface 45 facing the insulating film 20 via the barrier layer 30 extends toward the drain electrode 60 as it moves away from the insulating film 20. The gate electrode 40 of the semiconductor device model M2 has a shape in which the inclined surface 45 is inclined at a constant angle with respect to the insulating film 20 and extends toward the drain electrode 60 over a relatively short distance.

The semiconductor device model M3 illustrated in FIG. 9C includes, as the gate electrode 40, a gate electrode having a slant structure in which an inclined surface 45 facing the insulating film 20 via the barrier layer 30 extends toward the drain electrode 60 as it moves away from the insulating film 20. The gate electrode 40 of the semiconductor device model M3 has a shape in which the inclined surface 45 is inclined at a constant angle with respect to the insulating film 20 and extends toward the drain electrode 60 over a relatively long distance.

The semiconductor device model M4 illustrated in FIG. 9D includes, as the gate electrode 40, a gate electrode having a slant structure in which an inclined surface 45 facing the insulating film 20 via the barrier layer 30 extends toward the drain electrode 60 as it moves away from the insulating film 20. The gate electrode 40 of the semiconductor device model M4 has a shape in which the inclined surface 45 is inclined with respect to the insulating film 20 while being curved in a concave shape and extends toward the drain electrode 60 over a relatively long distance.

FIG. 10 illustrates an example of the simulation results for the electric field intensity distributions in the semiconductor device models M1 to M4. In FIG. 10, the electric field intensity distributions are superimposed with the positions of the drain-side edges 41 of the gate electrodes 40 in the semiconductor device models M1 to M4 being matched.

As illustrated in FIG. 10, in the semiconductor device model M1 in which the gate electrode 40 has the T-shaped structure, a relatively high electric field concentration occurs at the positions corresponding to the drain-side edge 41 of the gate electrode 40 and the edge (also referred to as “stepped portion edge”) 44 of the stepped portion 43 closer to the drain electrode 60.

On the other hand, in each of the semiconductor device models M2 to M4 in which the gate electrode 40 has a slant structure, the electric field concentration at the position corresponding to the drain-side edge 41 of the gate electrode 40 is relaxed, and the electric field concentration at the position corresponding to the stepped portion edge 44 of the T-shaped structure is also relaxed. In each of the semiconductor device models M3 and M4 in which the length of the inclined surface 45 of the gate electrode 40 is relatively long, the electric field tends to be dispersed as compared with the semiconductor device model M2 in which the length is relatively short. In the semiconductor device model M4 in which the inclined surface 45 of the gate electrode 40 is curved, the electric field tends to be dispersed more than in the semiconductor device model M3 in which the inclined surface 45 is not curved.

The gate electrodes 40 formed to have the slant structures make it possible to suppress a locally high electric field concentration as compared with the case of the gate electrode 40 formed to have the T-shaped structure. Further, by changing the shape of a gate electrode 40 having a slant structure, it is possible to change the position where the electric field occurs and the electric field intensity. The shape of the gate electrode 40 may be changed by adjusting the graded Al composition (Al composition distribution or Al concentration distribution) of the barrier layer 30 in which the gate electrode 40 is to be provided and adjusting the shape of the opening 31 formed by etching the barrier layer 30.

For example, the position of the drain-side edge 41 of the gate electrode 40 is set, and the position of an end 46 of the surface 30a located closer to the drain electrode 60 or the distance between the end 46 and the drain electrode 60 is set. Further, the thickness of the barrier layer 30 is set. By doing so, the amount of extension of the inclined surface 45 of the gate electrode 40 toward the drain electrode 60 is determined. The inclination of the inclined surface 45 of the gate electrode 40, at a constant angle or with curvature, is adjusted using the graded Al composition of the barrier layer 30 having the set thickness, that is, the Al concentration distribution. By adjusting the Al concentration distribution of the barrier layer 30, the shape of the opening 31 that is formed by etching is adjusted, and the shape of the gate electrode 40 to be formed in the opening 31, that is, the inclination (at a constant angle or with curvature) of the inclined surface 45 is adjusted.

### Second Embodiment

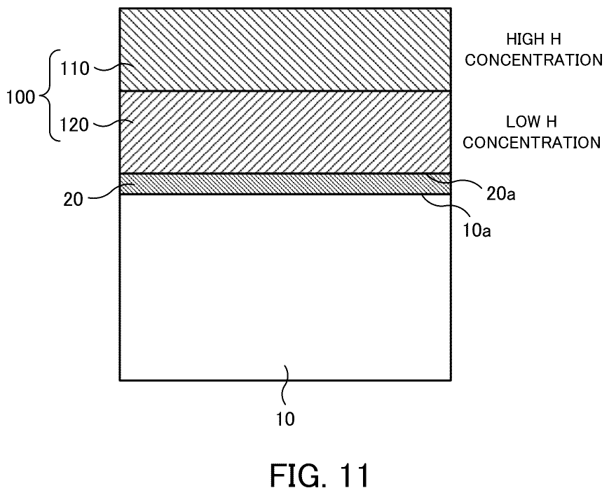

FIG. 11 illustrates an example of a barrier layer of a semiconductor device according to a second embodiment. FIG. 11 schematically illustrates a cross-sectional view of a main part of the example of the barrier layer. FIG. 11 illustrates the barrier layer provided on a substrate with an insulating film therebetween.

A barrier layer 100 as illustrated in FIG. 11 may be provided on the surface 10a side of the substrate 10 with an insulating film 20 therebetween. The barrier layer 100 illustrated in FIG. 11 includes a first layer 110 and a second layer 120. The first layer 110 is provided on the surface 20a side of the insulating film 20. The second layer 120 is provided between the surface 20a of the insulating film 20 and the first layer 110.

An insulating material having a relatively high concentration of H, for example, a-SiN is used for the first layer 110. As an example, a-SiN containing H at a concentration of 1.4×10²²/cm³ or less is used for the first layer 110. The concentration of H contained in the first layer 110 is set to be higher than the concentration of H contained in the second layer 120. The thickness of the first layer 110 is set in the range of 5 nm to 30 nm, for example.

An insulating material having a relatively low concentration of H, for example, a-SiN is used for the second layer 120. As an example, a-SiN containing H at a concentration of 1.0×10²²/cm³ or less is used for the second layer 120. The concentration of H contained in the second layer 120 is set to be lower than the concentration of H contained in the first layer 110. The thickness of the second layer 120 is set in the range of 5 nm to 30 nm, for example.

The first layer 110 and the second layer 120 are formed on the surface 10a side of the substrate 10 by the plasma enhanced chemical vapor deposition (PECVD) method and annealing.

For example, a-SiN is formed by the PECVD method on the surface 20a of the insulating film 20 formed on the surface 10a side of the substrate 10, and the a-SiN is annealed at a relatively high temperature of 600° C. to form the second layer 120. The second layer 120 formed in this manner (the second layer 120 before a second opening 121, to be described later, is formed) is also referred to as the “third layer”.

On the formed second layer 120, a-SiN is formed by the PECVD method, and the a-SiN is annealed at a relatively low temperature of 350° C. to form the first layer 110. The first layer 110 formed in this manner (the first layer 110 before a first opening 111, to be described later, is formed) is also referred to as the “fourth layer”.

In a-SiN, the higher the annealing temperature, the lower the H content. Therefore, by annealing the a-SiN formed using the PECVD method as described above at a relatively high temperature of 600° C., the second layer 120 containing a-SiN having a relatively low concentration of H is formed. By annealing the a-SiN formed using the PECVD method at a relatively low temperature of 350° C., the first layer 110 including a-SiN having a relatively high concentration of H is formed.

In this manner, the barrier layer 100 including the first layer 110 (or the fourth layer) and the second layer 120 (or the third layer) is formed. H contained in the first layer 110 and the second layer 120 of the barrier layer 100 is also referred to as the “first element”.

Next, an example of a method of manufacturing a semiconductor device using the above-described barrier layer 100 will be described.

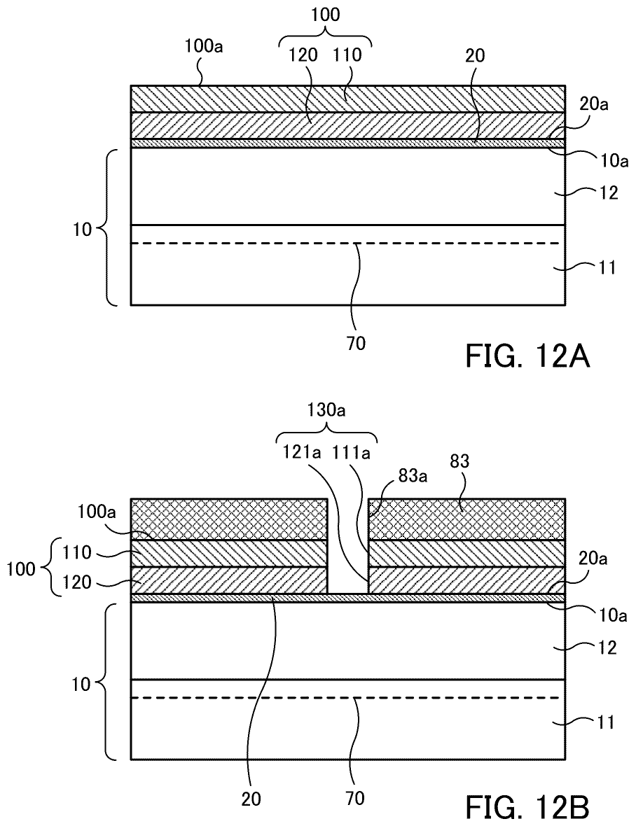

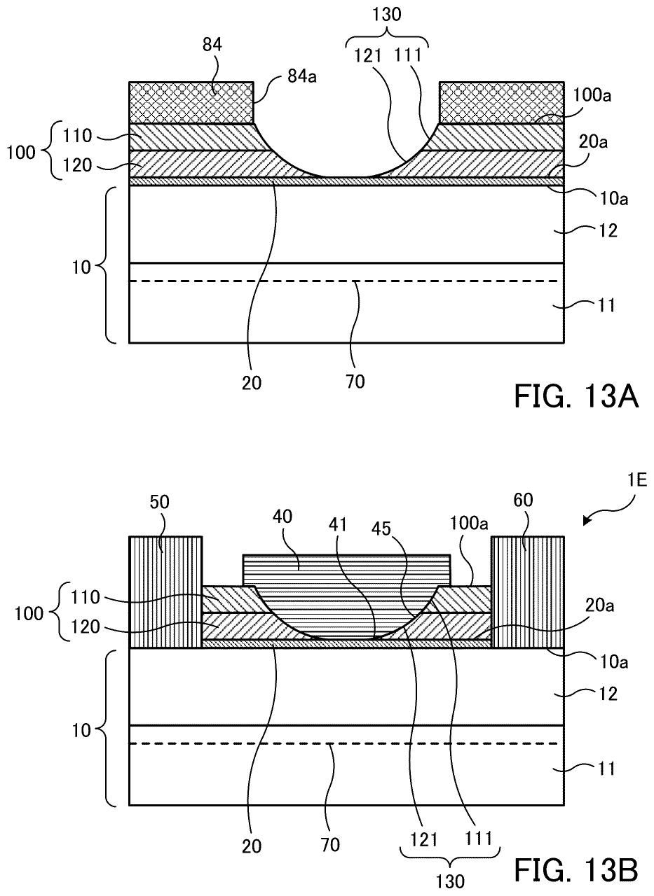

FIGS. 12A, 12B, 13A, and 13B are diagrams for describing an example of a semiconductor device manufacturing method according to the second embodiment. FIGS. 12A and 12B and FIGS. 13A and 13B each schematically illustrate a cross-sectional view of a main part in the example of the semiconductor device manufacturing process.

First, a structure as illustrated in FIG. 12A, that is, a structure in which the barrier layer 100 is formed on the substrate 10 with the insulating film 20 therebetween is formed.

The substrate 10 is formed by growing an electron transit layer 11, an electron supply layer 12, and others on a predetermined base substrate (not illustrated) using the MOCVD method or the like. For example, GaN is formed as the electron transit layer 11, and AlGaN is formed as the electron supply layer 12. The thickness of the electron transit layer 11 is set in the range of 100 nm to 200 nm, for example. The thickness of the electron supply layer 12 is set in the range of 5 nm to 30 nm, for example. In addition to the electron transit layer 11 and the electron supply layer 12, one or more of an initial layer, a buffer layer, a spacer layer, a back barrier layer, a cap layer, and others may be formed using predetermined nitride semiconductors in obtaining the substrate 10.

The insulating film 20 is formed on the surface 10a of the substrate 10 using the LPCVD method, the MOCVD method, or the like. For example, a-SiN is formed as the insulating film 20. In the formation of a-SiN using the LPCVD method or the MOCVD method, for example, the formation temperature is set in the range of 780° C. to 850° C. As a result, as the insulating film 20, a-SiN containing H at a concentration of 0.6×10²²/cm³ or less with a density of 2.8 g/cm³ or more is formed. The thickness of the insulating film 20 is set to 5 nm or less, for example, in the range of 4 nm to 5 nm. The a-SiN of the insulating film 20 is formed so that the concentration of H is lower than that of the barrier layer 100 formed as described later.

The barrier layer 100 is formed on the surface 20a of the insulating film 20 by the PECVD method and annealing.

For example, as described above, a-SiN is formed on the surface 20a of the insulating film 20 by the PECVD method, and the a-SiN is annealed at a relatively high temperature of 600° C. to form the second layer 120 (also referred to as the “third layer”). The thickness of the second layer 120 is set in the range of 5 nm to 30 nm, for example. Thus formed second layer 120 contains H at a concentration of 1.0×10²²/cm³ or less.

On the formed second layer 120, a-SiN is formed by the PECVD method, and the a-SiN is annealed at a relatively low temperature of 350° C. to form the first layer 110 (also referred to as the “fourth layer”). The thickness of the first layer 110 is set in the range of 5 nm to 30 nm, for example. Thus formed first layer 110 contains H at a concentration of 1.4×10²²/cm³ or less.

Thus, the barrier layer 100 including the first layer 110 containing a-SiN having a relatively high concentration of H and the second layer 120 containing a-SiN having a relatively low concentration of H is formed.

After forming the structure in which the barrier layer 100 is formed on the substrate 10 with the insulating film 20 therebetween, a resist 83 having an opening 83a in a region where the gate electrode 40 is to be formed is formed on the barrier layer 100, as illustrated in FIG. 12B. Using the resist 83 as a mask, dry etching using fluorine (F)-based gas is performed on the barrier layer 100 through the opening 83a.

Here, a-SiN having a lower concentration of H than a-SiN of the barrier layer 100 is used for the insulating film 20. The etching rate of a-SiN having a relatively low concentration of H with respect to F-based gas is lower than that of a-SiN having a relatively high concentration of H. Therefore, the barrier layer 100 having the relatively high concentration of H is etched using the insulating film 20 having the relatively low concentration of H as an etching stopper.

By etching the barrier layer 100 using the insulating film 20 as the etching stopper in this manner, a through hole 130a reaching the insulating film 20 is formed in the barrier layer 100, as illustrated in FIG. 12B. That is, in the barrier layer 100, a first through hole 111a penetrating through the first layer 110 is formed, and a second through hole 121a communicating with the first through hole 111a and penetrating through the second layer 120 is formed, so that the through hole 130a reaching the insulating film 20 is formed. After the through hole 130a is formed, the resist 83 is removed.

After the through hole 130a of the barrier layer 100 is formed, a resist 84 having an opening 84a in a region including the through hole 130a and the periphery thereof (the periphery located closer to regions where the source electrode 50 and the drain electrode 60 are to be formed) is formed on the barrier layer 100, as illustrated in FIG. 13A. Using the resist 84 as a mask, wet etching using ammonium fluoride (NH₄F) and hydrogen fluoride (HF) is performed on the barrier layer 100 through the opening 84a.

Here, the barrier layer 100 includes the first layer 110 containing a-SiN having the relatively high concentration of H and the second layer 120 containing a-SiN having the relatively low concentration of H. The etching rate of a-SiN having a relatively high concentration of H with respect to NH₄F and HF is higher than that of a-SiN having a relatively low concentration of H. Therefore, when the barrier layer 100 is wet-etched using NH₄F and HF, the first layer 110 is more easily etched than the second layer 120. For the insulating film 20, a-SiN containing H at a concentration lower than that of the second layer 120 is used. Therefore, when the barrier layer 100 is wet-etched using NH₄F and HF, the insulating film 20 functions as an etching stopper.

By etching the barrier layer 100 using the insulating film 20 as the etching stopper in this manner, an opening 130 whose opening width decreases in a direction from the surface 100a, which is located opposite to the insulating film 20, toward the insulating film 20 is formed in the barrier layer 100, as illustrated in FIG. 13A. More specifically, by increasing the opening width of the first through hole 111a, the first opening 111 is formed in the first layer 110. By increasing the opening width of the second through hole 121a, the second opening 121 is formed in the second layer 120. The first opening 111 and the second opening 121 form the opening 130 of the barrier layer 100. After the opening 130 is formed, the resist 84 is removed.

After the opening 130 of the barrier layer 100 is formed, the gate electrode 40, the source electrode 50, and the drain electrode 60 are formed, as illustrated in FIG. 13B.

For example, the barrier layer 100 and the insulating film 20 are etched to remove regions where the source electrode 50 and the drain electrode 60 are to be formed, and then a stack of Ta or Ti and Al is deposited in each region using the vapor deposition method, thereby forming the source electrode 50 and the drain electrode 60.

In addition, a stack of Ni and Au is deposited in the opening 130 of the barrier layer 100 using the vapor deposition method, thereby forming the gate electrode 40. The opening 130 of the barrier layer 100 has a shape in which the opening width increases in the direction from the insulating film 20 toward the surface 100a. By forming the gate electrode 40 in the opening 130, the gate electrode 40 having a slant structure in which its width increases in the direction from the insulating film 20 toward the surface 100a is formed. That is, the gate electrode 40 having the slant structure is formed in which the inclined surface 45 of the gate electrode 40 facing the surface 20a of the insulating film 20 via the barrier layer 100 extends toward the source electrode 50 and the drain electrode 60 as it moves away from the surface 20a of the insulating film 20.

Through the above-described process, a semiconductor device 1E as illustrated in FIG. 13B is manufactured, for example.

In this connection, the source electrode 50 and the drain electrode 60 may be formed on the surface 10a of the substrate 10 after the formation of the substrate 10 and before the formation of the insulating film 20 and the barrier layer 100. In this case, the insulating film 20 and the barrier layer 100 are formed on the surface 10a of the substrate 10 on which the source electrode 50 and the drain electrode 60 are formed, in the same way as the example of FIG. 12A. At this time, the insulating film 20 and the barrier layer 100 may be formed so as to cover the source electrode 50 and the drain electrode 60 on the surface 10a of the substrate 10. Alternatively, the source electrode 50 and the drain electrode 60 may be formed after the formation of the substrate 10 and the insulating film 20 and before the formation of the barrier layer 100. In this case, the source electrode 50 and the drain electrode 60 are formed on the surface 10a of the substrate 10 from which a part of the insulating film 20 is removed, and then the barrier layer 100 is formed in the same way as the example of FIG. 12A. In this case, the barrier layer 100 may be formed to cover the source electrode 50 and the drain electrode 60. Thereafter, the through hole 130a is formed in the same way as the example of FIG. 12B, the opening 130 is formed in the same way as the example of FIG. 13A, and the gate electrode 40 is formed in the same way as the example of FIG. 13B. Thus, the semiconductor device 1E is manufactured.

In the above-described method of manufacturing the semiconductor device, a barrier layer including the first layer 110 containing a-SiN having a relatively high concentration of H and the second layer 120 containing a-SiN having a relatively low concentration of H is formed as the barrier layer 100. Then, the opening 130 whose opening width decreases in the direction from the surface 100a toward the insulating film 20 is formed by the wet etching, using the fact that the etching rate is higher in a region having a high H concentration than in a region having a low H concentration in the wet etching using NH₄F and HF. The insulating film 20 functions as an etching stopper during the wet etching and during the dry etching performed prior to the wet etching. The gate electrode 40 is formed in the opening 130 thus formed in the barrier layer 100. The gate electrode 40 formed in the opening 130 has a slant structure.

With the above-described method of manufacturing the semiconductor device 1E using the etching, it is possible to obtain, with high productivity, the semiconductor device 1E including the gate electrode 40 having the slant structure, which is capable of suppressing the electric field concentration in the vicinity of the drain-side edge 41 and thus preventing a breakdown due to the electric field concentration. The insulating film 20 used as the etching stopper is also usable as a gate insulating film. Therefore, with the above-described method of manufacturing the semiconductor device 1E, it is possible to obtain, with high productivity, the semiconductor device 1E that is capable of suppressing the occurrence of gate leakage current and thus preventing a decrease in the maximum drain current due to the gate leakage current.

With the above-described manufacturing method, it is possible to efficiently manufacture the high-performance semiconductor device 1E that is capable of minimizing its performance degradation that is caused by the electric field concentration and gate leakage current.

The above example describes the barrier layer 100 having a two-layer structure of the first layer 110 and the second layer 120. In this connection, the number of layers in the barrier layer is not limited to two. Even in the case where a barrier layer has a structure with three or more layers, it is possible to obtain the same configuration as the semiconductor device 1E, by using a barrier layer that has a higher concentration of H than the insulating film 20 and has an H concentration distribution in which the concentration is higher on the surface 100a side than on the insulating film 20 side. Specifically, it is possible to obtain a semiconductor device that includes a barrier layer having an opening whose opening width decreases in the direction from the surface 100a toward the insulating film 20, and a gate electrode 40 having a slant structure provided in the opening.

In addition, the above example describes using a-SiN containing H for the insulating film 20. The insulating film 20 of the semiconductor device 1E is not limited to a-SiN containing H, and another insulating material is usable as long as it is able to function as both an etching stopper and a gate insulating film.

In the semiconductor device 1E, the shape of the gate electrode 40 having the slant structure may be changed so as to change the position where the electric field occurs and the electric field intensity. The gate electrode 40 is formed in a desired shape by adjusting the H concentration distribution of the barrier layer 100 in which the gate electrode 40 is to be provided and adjusting the shape of the opening 31 formed in the barrier layer 100 by etching.

For example, the position of the drain-side edge 41 of the gate electrode 40 is set, and the position of an end of the surface 100a located closer to the drain electrode 60 or the distance between the end and the drain electrode 60 is set. Further, the thickness of the barrier layer 100 is set. This determines the amount of extension of the inclined surface 45 of the gate electrode 40 toward the drain electrode 60. Then, in the barrier layer 100 having the thickness, the number of layers in which H concentration increases toward the surface 100a and the thickness of each layer are set. Thus, the shape of the opening 130 formed by etching is adjusted, and the shape of the gate electrode 40 formed in the opening 130 is adjusted.

The first and second embodiments have been described.

The semiconductor devices 1A to 1E and the like described above are applicable to various electronic devices. As examples, the following describes cases where a semiconductor device having the above-described configuration is applied to a semiconductor package, a power factor correction circuit, a power supply device, and an amplifier.

### Third Embodiment

Here, an application example of a semiconductor device having the above-described configuration to a semiconductor package will be described as a third embodiment.

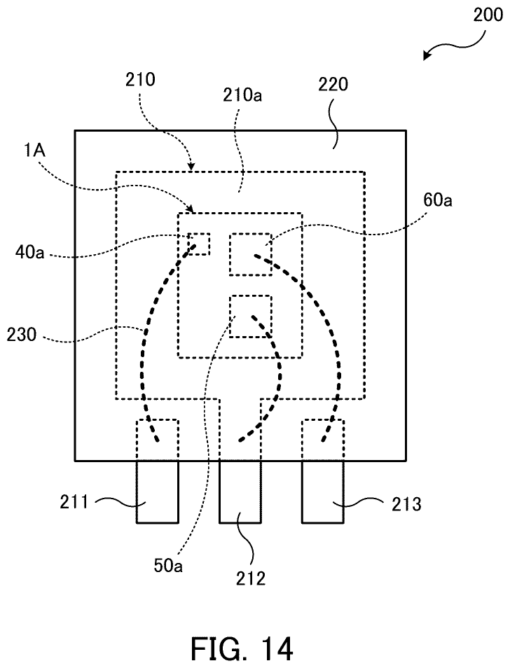

FIG. 14 is a diagram for describing an example of the semiconductor package according to the third embodiment. FIG. 14 schematically illustrates a plan view of a main part of the example of the semiconductor package.

The semiconductor package 200 illustrated in FIG. 14 is an example of a discrete package. As an example, the semiconductor package 200 includes the semiconductor device 1A (FIGS. 1A and 1B, etc.) described in the first embodiment, a lead frame 210 on which the semiconductor device 1A is mounted, and a resin 220 that seals the semiconductor device 1A and the lead frame 210.

The semiconductor device 1A is mounted on, for example, a die pad 210a of the lead frame 210 using a die attach material L or the like (not illustrated). The semiconductor device 1A includes a pad 40a connected to the gate electrode 40, a pad 50a connected to the source electrode 50, and a pad 60a connected to the drain electrode 60. The pad 40a, the pad 50a, and the pad 60a are respectively connected to a gate lead 211, a source lead 212, and a drain lead 213 of the lead frame 210 using wires 230 made of Au, Al, or the like. The lead frame 210, the semiconductor device 1A mounted thereon, and the wires 230 connecting them are sealed with the resin 220, with the gate lead 211, the source lead 212, and the drain lead 213 each partially exposed.

An external connection electrode that is connected to the source electrode 50 may be provided on the surface of the semiconductor device 1A opposite to the surface on which the pad 40a connected to the gate electrode 40 and the pad 60a connected to the drain electrode 60 are provided. The external connection electrode may be connected to the die pad 210a connected to the source lead 212 using a conductive bonding material such as solder.

For example, the semiconductor package 200 using the semiconductor device 1A described in the first embodiment is obtained. As described earlier, in the semiconductor device 1A, the barrier layer including the first layer and the second layer containing the predetermined first element at different concentrations is provided on the substrate with the insulating film serving as the etching stopper and the gate insulating film therebetween. An opening whose opening width decreases toward the insulating film is formed in the barrier layer, by utilizing the difference in etching rate between the first layer and the second layer, and the gate electrode is provided in the opening. The gate electrode provided in the opening has a slant structure. As a result, the high-performance semiconductor device 1A is obtained, which is capable of minimizing its performance degradation that is caused by electric field concentration and gate leakage current. The semiconductor package 200 is obtained using this semiconductor device 1A.

The above example uses the semiconductor device 1A. A semiconductor package may be similarly obtained using one of the other semiconductor devices 1B to 1E and the like.

### Fourth Embodiment

Here, an application example of a semiconductor device having the above-described configuration to a power factor correction circuit will be described as a fourth embodiment.

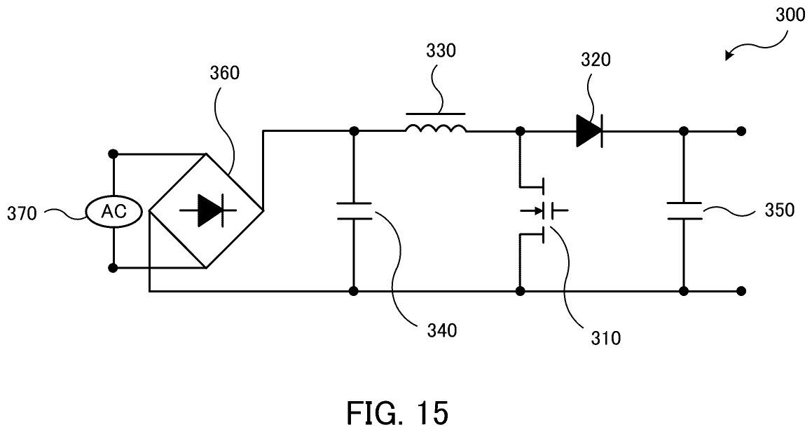

FIG. 15 is a diagram for describing an example of the power factor correction circuit according to the fourth embodiment. FIG. 15 illustrates an equivalent circuit diagram of the example of the power factor correction circuit.

The power factor correction (PFC) circuit 300 illustrated in FIG. 15 includes a switch element 310, a diode 320, a choke coil 330, a capacitor 340, a capacitor 350, a diode bridge 360, and an alternating current power supply 370 (AC).

In the PFC circuit 300, the drain electrode of the switch element 310 is connected to the anode terminal of the diode 320 and one terminal of the choke coil 330. The source electrode of the switch element 310 is connected to one terminal of the capacitor 340 and one terminal of the capacitor 350. The other terminal of the capacitor 340 and the other terminal of the choke coil 330 are connected to each other. The other terminal of the capacitor 350 and the cathode terminal of the diode 320 are connected to each other. A gate driver is connected to the gate electrode of the switch element 310. The AC power supply 370 is connected between both terminals of the capacitor 340 via the diode bridge 360, and a direct current power supply (DC) is taken out from between both terminals of the capacitor 350.

For example, one of the above-described For semiconductor devices 1A to 1E and the like is used for the switch element 310 of the PFC circuit 300 having such a configuration. As described earlier, in each of the semiconductor devices 1A to 1E and the like, a barrier layer including a first layer and a second layer containing a predetermined first element at different concentrations is provided on a substrate with an insulating film serving as both an etching stopper and a gate insulating film therebetween. An opening whose opening width decreases toward the insulating film is formed in the barrier layer, by utilizing the difference in etching rate between the first layer and the second layer, and a gate electrode is provided in the opening. The gate electrode provided in the opening has a slant structure. Accordingly, the high-performance semiconductor devices 1A to 1E and the like are obtained, which are capable of minimizing their performance degradation that is caused by electric field concentration and gate leakage current. The PFC circuit 300 is obtained using one of these semiconductor devices 1A to 1E and the like.

### Fifth Embodiment

Here, an application example of a semiconductor device having the above-described configuration to a power supply device will be described as a fifth embodiment.

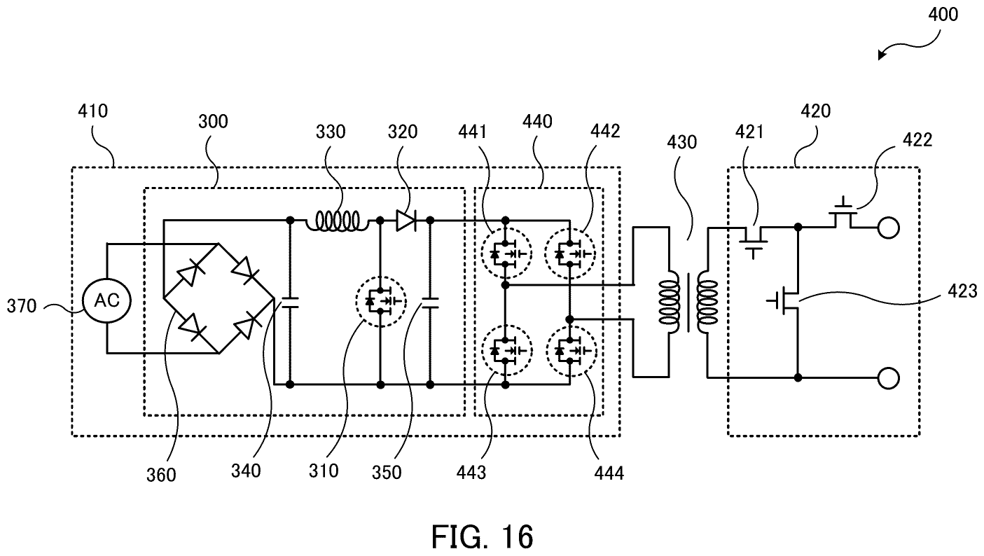

FIG. 16 is a diagram for describing an example of the power supply device according to the fifth embodiment. FIG. 16 illustrates an equivalent circuit diagram of the example of the power supply device.

The power supply device 400 illustrated in FIG. 16 includes a primary circuit 410, a secondary circuit 420, and a transformer 430 provided between the primary circuit 410 and the secondary circuit 420.

The primary circuit 410 includes the PFC circuit 300 as described in the fourth embodiment and an inverter circuit connected between both terminals of the capacitor 350 of the PFC circuit 300. The inverter circuit is, for example, a full-bridge inverter circuit 440. The full-bridge inverter circuit 440 includes a plurality of switch elements, for example, four switch elements 441, 442, 443, and 444.

The secondary circuit 420 includes a plurality of switch elements, for example, three switch elements 421, 422, and 423.

For example, in the power supply device 400 having the above configuration, the semiconductor devices 1A to 1E and the like are used for the switch element 310 of the PFC circuit 300 and the switch elements 441 to 444 of the full-bridge inverter circuit 440 in the primary circuit 410. For example, as the switch elements 421 to 423 of the secondary circuit 420 in the power supply device 400, typical MIS field-effect transistors using Si are used. As described earlier, in each of the semiconductor devices 1A to 1E and the like, a barrier layer including a first layer and a second layer containing a predetermined first element at different concentrations is provided on a substrate via an insulating film serving as an etching stopper and a gate insulating film therebetween. An opening whose opening width decreases toward the insulating film is formed in the barrier layer, by utilizing the difference in etching rate between the first layer and the second layer, and a gate electrode is provided in the opening. The gate electrode provided in the opening has a slant structure. Accordingly, the high-performance semiconductor devices 1A to 1E and the like are obtained, which are capable of minimizing their performance degradation that is caused by electric field concentration and gate leakage current. The power supply device 400 is obtained using the above semiconductor devices 1A to 1E and the like.

### Sixth Embodiment

Here, an application example of a semiconductor device having the above-described configuration to an amplifier will be described as a sixth embodiment.

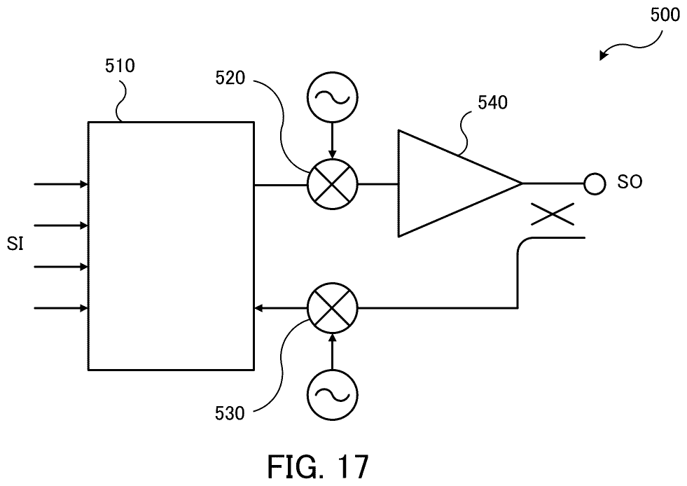

FIG. 17 is a diagram for describing an example of the amplifier according to the sixth embodiment. FIG. 17 illustrates an equivalent circuit diagram of the example of the amplifier.

The amplifier 500 illustrated in FIG. 17 includes a digital predistortion circuit 510, a mixer 520, a mixer 530, and a power amplifier 540.

The digital predistortion circuit 510 compensates for nonlinear distortion of an input signal. The mixer 520 mixes an input signal SI whose nonlinear distortion has been compensated for with an AC signal. The power amplifier 540 amplifies a signal obtained by mixing the input signal SI with the AC signal. In the amplifier 500, for example, by switching a switch, an output signal SO is mixed with the AC signal by the mixer 530, and the resultant is sent to the digital predistortion circuit 510. The amplifier 500 is usable as a high-frequency amplifier or a high-power amplifier.

The semiconductor devices 1A to 1E and the like are used for the power amplifier 540 of the amplifier 500 having the above configuration. As described earlier, in each of the semiconductor devices 1A to 1E and the like, a barrier layer including a first layer and a second layer containing a predetermined first element at different concentrations is provided on a substrate with an insulating film serving as an etching stopper and a gate insulating film therebetween. An opening whose opening width decreases toward the insulating film is formed in the barrier layer, by utilizing the difference in etching rate between the first layer and the second layer, and a gate electrode is provided in the opening. The gate electrode provided in the opening has a slant structure. Accordingly, the high-performance semiconductor devices 1A to 1E and the like are obtained, which are capable of minimizing their performance degradation that is caused by electric field concentration and gate leakage current. The amplifier 500 is obtained using one of these semiconductor devices 1A to 1E and the like.

Various electronic devices (the semiconductor package 200, the PFC circuit 300, the power supply device 400, and the amplifier 500 described in the third to sixth embodiments, and others) to which the semiconductor devices 1A to 1E and the like are applied may be mounted on various electronic apparatuses or electronic devices. For example, they may be mounted on various electronic apparatuses and electronic devices such as computers (personal computers, supercomputers, servers, and others), smartphones, mobile phones, tablet terminals, sensors, cameras, audio devices, measurement devices, inspection devices, manufacturing devices, transmitters, receivers, and radar devices.

According to one aspect, it is achieved to obtain a high-performance semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a substrate having a first surface on a first surface side thereof;
a first layer provided on the first surface side of the substrate, containing a first element at a first concentration, and including a first opening with a first opening width; and
a second layer provided between the first surface of the substrate and the first layer, containing the first element at a second concentration different from the first concentration, and including a second opening with a second opening width smaller than the first opening width, the second opening communicating with the first opening of the first layer.

2. The semiconductor device according to claim 1, wherein the first layer and the second layer are amorphous.

3. The semiconductor device according to claim 1, wherein each of the first layer and the second layer contains the first element and includes a nitride of a second element different from the first element.

4. The semiconductor device according to claim 3, wherein the first element is aluminum and the second element is gallium, and
the first concentration of the first element is lower than the second concentration thereof.

5. The semiconductor device according to claim 3, wherein the first element is hydrogen and the second element is silicon, and
the first concentration of the first element is higher than the second concentration thereof.

6. The semiconductor device according to claim 1, further comprising an insulating film provided between the first surface and the second layer,
wherein the second opening of the second layer reaches the insulating film.

7. The semiconductor device according to claim 1, further comprising a barrier layer provided on the first surface side of the substrate and including an opening whose opening width increases in a direction from the substrate toward a side of the barrier layer opposite to the substrate,
wherein each of the first layer and the second layer is a part of the barrier layer, and
wherein each of the first opening of the first layer and the second opening of the second layer is a part of the opening of the barrier layer.

8. The semiconductor device according to claim 7, further comprising:
a gate electrode provided in the opening of the barrier layer; and
a drain electrode provided on the first surface side of the substrate so as to be separate from the gate electrode,
wherein the opening has a shape such that a surface of the gate electrode facing the first surface via the barrier layer extends toward the drain electrode as the surface of the gate electrode moves away from the first surface.

9. A semiconductor device manufacturing method comprising:
forming a first layer on a first surface side of a substrate, the substrate having a first surface on the first surface side thereof, the first layer containing a first element at a first concentration and including a first opening with a first opening width; and
forming a second layer between the first surface of the substrate and the first layer, the second layer containing the first element at a second concentration different from the first concentration and including a second opening with a second opening width smaller than the first opening width, the second opening communicating with the first opening of the first layer.

10. The semiconductor device manufacturing method according to claim 9, further comprising:
before forming the first layer and the second layer,
forming a third layer on the first surface side of the substrate, the third layer containing the first element at the second concentration, and
forming a fourth layer on a side of the third layer opposite to the substrate, the fourth layer containing the first element at the first concentration,
wherein the forming of the first layer includes etching the fourth layer to form the first opening, thereby forming the first layer including the first opening, and
wherein the forming of the second layer includes etching the third layer to form the second opening, thereby forming the second layer including the second opening.

11. The semiconductor device manufacturing method according to claim 9, wherein the first layer and the second layer are amorphous.

12. The semiconductor device manufacturing method according to claim 9, wherein each of the first layer and the second layer contains the first element and includes a nitride of a second element different from the first element.

13. The semiconductor device manufacturing method according to claim 12, wherein the first element is aluminum and the second element is gallium, and
the first concentration of the first element is lower than the second concentration thereof.

14. The semiconductor device manufacturing method according to claim 12, wherein the first element is hydrogen and the second element is silicon, and
the first concentration of the first element is higher than the second concentration thereof.

15. The semiconductor device manufacturing method according to claim 9, further comprising forming an insulating film between the first surface and the second layer,
wherein the forming of the second layer includes forming the second layer including the second opening that reaches the insulating film.

16. The semiconductor device manufacturing method according to claim 9, further comprising forming a barrier layer on the first surface side of the substrate, the barrier layer including an opening whose opening width increases in a direction from the substrate toward a side of the barrier layer opposite to the substrate,
wherein the forming of the barrier layer includes forming the first layer and forming the second layer.

17. The semiconductor device manufacturing method according to claim 16, further comprising:
forming a gate electrode in the opening of the barrier layer; and
forming a drain electrode on the first surface side of the substrate, the drain electrode being provided so as to be separate from the gate electrode,
wherein the forming of the barrier layer includes forming the barrier layer including the opening having a shape such that a surface of the gate electrode facing the first surface via the barrier layer extends toward the drain electrode as the surface of the gate electrode moves away from the first surface.

18. An electronic device including a semiconductor device, the semiconductor device comprising:
a substrate having a first surface on a first surface side thereof;
a first layer provided on the first surface side of the substrate, containing a first element at a first concentration, and including a first opening with a first opening width; and
a second layer provided between the first surface of the substrate and the first layer, containing the first element at a second concentration different from the first concentration, and including a second opening with a second opening width smaller than the first opening width, the second opening communicating with the first opening of the first layer.
